(19) United States
(12) Patent Application Publication
(10) Pub. No.: US 2005/0268848 A1
(43) Pub. Date: Dec. 8, 2005

(54) Atomic layer deposition apparatus and process

(75) Inventor: Chia-Gee Wang, Millwood, NY (US)

Correspondence Address: LADAS & PARRY, 26 WEST 61ST STREET, NEW YORK, NY, 10023, US

(73) Assignee: NANODYNAMICS, INC

(21) Appl. No.: 11/116,140

(22) Filed: Apr. 27, 2005

Related U.S. Application Data
(60) Provisional application No. 60/566,108, filed on Apr. 28, 2004.

(51) Int. Cl. C23C 16/00

(52) U.S. Cl. 118/719; 427/248.1

(57) ABSTRACT

An atomic layer deposition apparatus for depositing a plurality of ultra-thin layers onto an epitaxial substrate comprises first and second chambers each having an inlet for a gas to be adsorbed on an epitaxial substrate, a transport chamber disposed between the first and second chambers, a loading chamber connected to the transport chamber for storing, loading and unloading epitaxial substrates, an outer chamber enclosing the first, second and transport chambers and at least partially enclosing said loading chamber, and means for individually heating the chambers and evacuating the chambers to ultra high vacuum pressures. An atomic layer deposition process comprises moving an epitaxial silicon substrate from a transport chamber to a first chamber and introducing a gas for formation of a first, adsorbed atomic layer, transferring the substrate through the transport chamber and into the second chamber and introducing a silicon-containing gas for formation of a second, ultra-thin epitaxial silicon layer, and maintaining different temperatures in the first and second chambers.

### CROSS-RELATED APPLICATION

This application claims the benefit of U.S. Provisional Application No. 60/566,108 filed Apr. 28, 2004 and incorporates the same by reference.

### BACKGROUND OF THE INVENTION

1. Field of the Invention

The invention relates to an Atomic Layer Deposition (ALD) apparatus for forming alternating ultra-thin layers on an epitaxial substrate, and to an ALD process in which a gas is adsorbed on an epitaxial silicon substrate to form a first, atomic layer followed by forming a second, ultra-thin epitaxial silicon layer.

2. Description of the Related Art

An ALD apparatus is disclosed in U.S. Pat. Nos. 6,042,652 to Hyun et al. and 6,461,436 to Campbell et al.; and an ALD process is disclosed in Campbell et al. U.S. Pat. No. 6,716,284. These patents use a single reactor (depositing chamber) for ALD.

Production of silicon wafers in a single chamber is described in Yang U.S. Pat. No. 6,599,815.

Apparatus and methods for manufacturing silicon wafers using multiple chambers and a loading chamber are described in Maydan et al. U.S. Pat. No. 4,951,601 and Ihantola U.S. Pat. No. 6,174,366. These patents do not involve ALD techniques, and use different chambers for different sequential steps in silicon wafer production such as chemical vapor deposition and plasma etching. Epitaxial growth occurs in a single one of the multiple chambers in contrast to the apparatus and process of the present invention.

U.S. Pat. No. 5,233,218 discloses a silicon-on-insulator (SOI) type semiconductor wafer which is produced either by an SIMOX (Separation by Implanted Oxygen) process or by laminating two silicon wafers, one having a silicon oxide layer and the other being all silicon.

Structures comprising epitaxially grown alternate layers of SiO₂ and Si are disclosed in U.S. Pat. No. 5,216,262 issued to Raphael Tsu.

The following publications describe SOI structures comprising superlattices having alternating epitaxial layers of silicon and oxygen (Si/O):
Wang et al. U.S. Pat. No. 6,376,337 and U.S. application Ser. No. 09/617,511;
R. Tsu, A. Filios, C. Lofgren, D. Cahill, J. VanNostrand, C. G. Wang, Solid-State Electronics, 40:221-223 (1996); and
R. Tsu, A. Filios, C. Lofgren, K. Dovidenko and C. G. Wang, Electrochem and Solid State Lett., 1:80-82 (1998).

A superlattice comprising alternating epitaxial layers of silicon and carbon is described in Wang et al. U.S. Provisional Application 60/408,358 and corresponding U.S. application filed thereon on Apr. 14, 2004.

### BRIEF SUMMARY OF THE INVENTION

According to the invention there is provided an atomic layer deposition apparatus for depositing a plurality of ultra-thin layers onto an epitaxial substrate, said apparatus comprising: a first chamber having an inlet for a gas to be adsorbed on an epitaxial substrate; a second chamber having an inlet for a gas to be adsorbed on said epitaxial substrate; a transport chamber disposed between said first and second chambers for transporting and annealing said epitaxial substrate; a loading chamber connected to the transport chamber for storing, loading and unloading epitaxial substrates, said loading chamber comprising a vacuum gate for isolating the loading chamber from the external atmosphere; the transport chamber comprising transporting means for transferring epitaxial substrates to and from each of said first, second and loading chambers; the first chamber being connected to the transport chamber by a first conduit and the second chamber being connected to the transport chamber by a second conduit, each conduit allowing passage of substrates and comprising a vacuum gate; an outer chamber enclosing the first, second and transport chambers and at least partially enclosing said loading chamber; means for heating the first, second and transport chambers to temperatures individually selected for each chamber; means for evacuating the first, second, transport, loading and outer chambers to ultra high vacuum pressures individually selected for each chamber.

Also provided according to the invention is an atomic layer deposition process which comprises: moving an epitaxial silicon substrate into a transport chamber located between a first chamber and a second chamber, said chambers being heated and evacuated to ultra high vacuum pressures; transferring the substrate into the first chamber and introducing a gas for adsorption onto the substrate and formation of an adsorbed atomic first layer; transferring the substrate having the first layer back into the transport chamber and then into the second chamber; introducing a silicon-containing gas into the second chamber for adsorption onto the first layer and formation of an ultra-thin epitaxial silicon second layer; maintaining different temperatures in the first and second chambers, said different temperatures being selected to form the first and second layers and maintain them without structural degradation.

According to the invention there is provided an atomic layer deposition apparatus for depositing a plurality of ultra-thin layers onto an epitaxial substrate, said apparatus comprising: a load stack which contains wafers that can be fed into a cyclical transport path, which commences with a series of several heating plates that will increase the wafer temperature from 450° C. to 650° C. or 850° C.; a silicon deposition stack where the top wafer in the stack receives silicon ions or silane vapor at the elevated temperature; from the bottom of the stack, a series of temperature controlled plates that will reduce the temperature of the wafer to 150° C.; an optional wafer removal/unload stack; or an oxygen deposition half stack loading upwards; a heating plate to raise the temperature of the wafer to 350° C. feeding into an optional a carbon deposition half stack loading upwards: a transport from the top of the optional carbon deposition half stack to the series of heating plates that begin the cycle to enter the silicon deposition chamber. The silicon deposition using either silicon ions or silane gas is achieved by ALD at the top of the stack. The oxygen deposition and optional carbon deposition are achieved by CVD throughout the half stack units. One cycle round of this unit provides an atomic layer of silicon, an atomic layer of oxygen and finally, the optional carbon to produce a multilayered Si/O or Si/C wafer. The entire cyclical system is contained in a chamber system providing a vacuum of 1×10⁻⁶ Torr or better.

### BRIEF DESCRIPTION OF THE DRAWINGS

FIG. 1 is a schematic plan view of an embodiment of the apparatus of the invention, showing the gas deposition, transport and loading chambers.

FIG. 2 is a schematic plan view of the apparatus shown in FIG. 1, surrounded by an outer chamber, according to the invention.

FIG. 3 is a schematic elevational view of the apparatus shown in FIG. 2.

FIG. 4 shows a further embodiment in which a dual chamber system is provided for the construction of Si/O superlattice wafers

FIG. 5 shows the treatment conditions carried out in the embodiment of FIG. 4.

### DETAILED DESCRIPTION OF THE INVENTION

SOI, or silicon-on-insulator, was originally developed for radiation hardening. In a depleted semiconductor region, the depth of the depletion is proportional to the level of random ionizing radiation signals, and an insulation layer placed beneath the epi-surface layer would terminate the depletion thickness at the insulation and reduce the signals created by the random electron-hole pairs generated in the depletion thickness. Over the decades, as the device dimensions reduced from 10s of μm with ever increasing speed, the cross-talk between devices became a serious limiting factor for high speed performance. The use of SOI wafers helps isolate the devices from each other and from the bulk substrate and eliminates the need for shallow trench isolation. Among other benefits, it allows more room for smaller, faster devices with reduced processing steps.

SOI wafers were originally produced under the SIMOX process, by implantation of oxygen ions to a wafer surface to form a buried oxygen (BOX) layer. The implantation of oxygen would crack the top epi-layer of the wafer beyond repair (anneal), and reduce the mobility of the material by more than 50%. In addition, the non-uniformity of the insulating thickness and of the top epi-layer, make the SOI wafer produced under the SIMOX process unattractive. In 2001, the process was modified to perform the ion implantation of oxygen at an elevated temperature in order to provide the silicon atoms with sufficient surface mobility to repair the scattering damages from oxygen ions as soon as they are created. Also the quality of the ion beam was improved and now the SOI wafers from the SIMOX process have become a viable product.

The most well known SOI product currently is bonded wafers. This approach uses two silicon wafers A and B. First a thin SiO₂ layer is placed on A, and the A surface with SiO₂ is bonded to wafer B. Protons are implanted into the back side of the B and the bonded wafer is annealed in order to peal off most of the B part. The part of the B wafer being pealed off is used for the next wafer A to support a new SiO₂ surface layer, while the B part remaining on the first A is polished and coated with an epi-surface (epi-wafer) treatment. Chemical and mechanical polishing is used to shave the top layer of the bonded wafers from a μm to a level of 50 nm or so with reasonable yield. But the bonding, the cut and the shaving are costly procedures.

With a bandgap of 9.2 eV, SiO₂ is one of the best insulating materials. Unfortunately, it has a lattice mismatch of 38% with silicon, and cannot be made epitaxially when added to silicon. The growth of SiO₂ on silicon is necessarily amorphous, and contains a very high level of dangling bonds because of the lattice mismatch. These dangling bonds must be passivated with hydrogen in order to be useful as MOS for device fabrications. MOS has become the basic structure for silicon devices. Using a Si/O superlattice, even having oxygen participating in less than 1/10 of the layers, the bandgap of Si/O is already at 2.3 eV. Using a bandgap of 2.3 eV for Si/O its breakdown voltage may be estimated to be approximately 3.5 MV/cm as scaled from that of SiO₂ at 9.2 eV and 10 MV/cm, including a 38% difference in lattice dimensions. This Si/O superlattice has a lattice mismatch at under 1% and can be made with very low interface defect density. The present invention is directed to make an epi-SOI wafer with an ultra-thin epi-insulator as well as ultra-thin epi-silicon layers because of great need for such an epi-SOI. While the current method of producing SOI must struggle to reach ultra-thin layers, the epi-SOI process starts with the deposition of a single atomic layer uniformly and at low cost.

The epi-SOI made with the apparatus or by the process of the present invention can meet the goals of providing ultra uniform and ultra thin parameters for both the insulating layer and the top epi-layer. Superlattice technology can provide the thickness to a controlling accuracy of a single atomic layer, and can do the fabrication at a greatly reduced cost as compared to the current methods mentioned above.

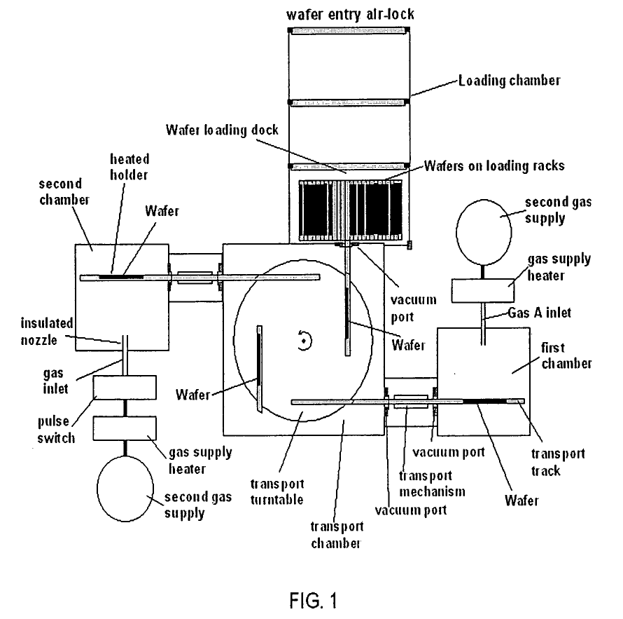

We have used multi-chamber MBE (molecular beam epitaxy) equipment in research to make an Si/O superlattice, but MBE has a low throughput and cannot satisfy usual silicon processing needs. Therefore, we have found it necessary to use an HV-CVD (high vacuum-chemical vapor deposition), or an atomic layer deposition (ALD) where the silicon deposition can be controlled at atomic level. The ALD apparatus according to the invention includes a separate chamber for, e.g., oxygen exposure without contaminating, e.g., silicon deposition done in a second chamber. These two chambers are separated by a gate-lock which may be injected with inert gas. FIG. 1 shows the dual-chamber ALD.

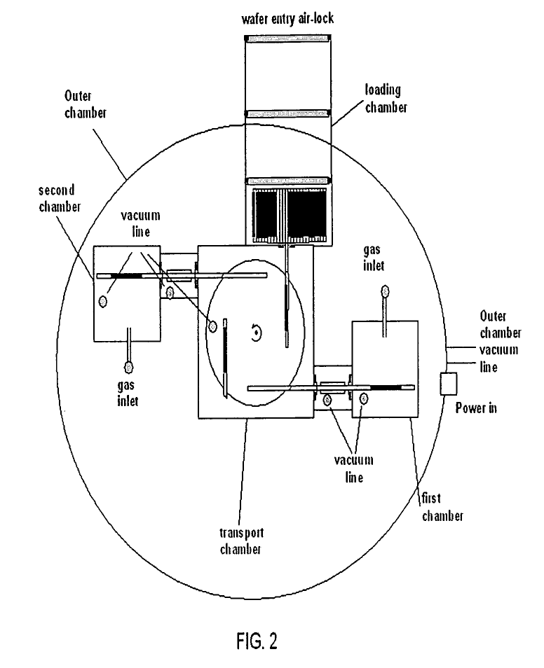

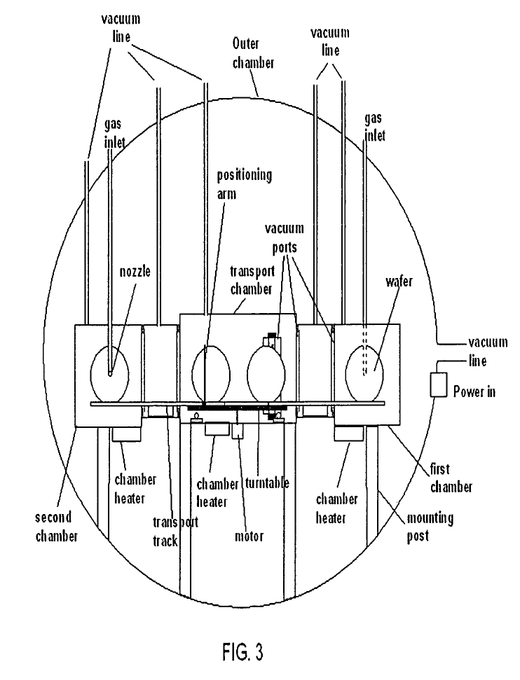

For binary superlattice fabrication, the invention provides a first chamber for one gas and a second chamber for another gas, in a way without mixing the gases. Between the chambers is a transport chamber which receives substrates, e.g., silicon wafers, from the two gas adsorption chambers, rotates them and sends them back to one or the other of the adsorption chambers. Wafers in the three chambers are kept at different temperatures, with the higher temperature for thermal cracking of e.g. silane which can be injected by an insulated nozzle, and the lower temperatures used for exposure to a gas such as oxygen. The transport chamber has three rectangular gates one for each gas adsorption chamber and one for wafer loading. As shown in FIGS. 2 and 3, the ALD system, at over 500° C. and high vacuum, must be housed in an UHV enclosure (the outer chamber) which isolates the chambers inside from the ambient temperature and pressure. At a low pressure gradient, the adsorption and transport chambers can be constructed with thin flat stainless steel walls at low cost. A cassette system may be used to supply wafers as well as to store the processed wafers so that the enclosed system can operate continuously, with the cassettes moving in and out of the sealed ALD system. The temperature range is selected high enough to allow sufficient mobility for the surface atoms to form the epitaxial structure and to thermally decompose e.g. the SiH₄ molecule, but not high enough to allow the surface oxygen ions to diffuse throughout the silicon matrix.

For a silicon-based superlattice using an extremely thin layer of foreign atoms to be sandwiched between epi-layers of silicon, the ultra-thin layer of foreign atoms can be made self-limiting when the catalytic function of the silicon surface structure is employed, and the foreign atoms can be large foreign molecules. Allowing the catalytic function to operate at 700° C. or more, the foreign molecules would undergo thermal cracking on the silicon surface so that the deposition process can occur under the usual CVD instead of exclusively under the MBE. While silicon does not have a direct bandgap for strong optical emissions, the silicon-based superlattices do provide very strong and steady opto-luminescence with wavelength mostly in the visible range. These emissions also confirm the atomic arrangement of the superlattice surface.

In the process of the invention, the ultra high vacuum pressures typically are such that:
the outer chamber is evacuated to a pressure of between about 10⁻⁸ torr and about 10⁻⁹ torr;
the first and second chambers and the transport chamber are evacuated to a pressure of between about 10⁻³ torr to about 10⁻⁶ torr;
the first and second chambers are maintained at a lower pressure than the pressure in the transport chamber such that residual gas in either of the first and second chambers does not enter the other of said chambers.

Thus mixing of the different gases is avoided, and following adsorption of introduced gases, residual gases in the first and second chambers may be removed by evacuation.

Known apparatus using a highly evacuated chamber or multiple chambers must be constructed to withstand a high pressure difference with respect to the atmosphere, and to have substantial insulation.

Atmospheric pressure is 760 torr, (14.51 lbs/inc²). At a chamber vacuum of one torr or less, the known apparatus chamber wall must sustain 760−1=759 torr (14.51 lbs/inch²). For a large vacuum chamber, the pressure burden can be tons on the wall, and the wall must be spherical. Otherwise, a flat wall even with an inch thick steel would still be pressed to become warped. A large, round chamber wall is difficult to connect with flat openings such as the glass windows, vacuum sealed gates, transport ports, etc. so the vacuum chamber is usually constructed as small as possible. Also in known apparatus, inside the chamber samples may be maintained at 700° C. or higher, while the chamber wall is exposed to room temperature. The wall can be only a few cm away from the hot sample. The sample must therefore, be heated aggressively and the chamber wall must be cooled aggressively in order to maintain such a large temperature difference. In addition, the sample temperature must be kept uniformly throughout its surface. Combining all the requirements, they become a costly and almost impossible task.

However, in the apparatus of the present invention the outer chamber may comprise a wall, usually spherical, constructed of steel sufficiently thick to withstand a pressure difference between a pressure inside said chamber of between about 10⁻⁸ torr and about 10⁻⁹ torr, and atmospheric pressure outside said chamber. The outer chamber may be insulated in some cases. The first, second and transport chambers then may be made of thin rectangular stainless steel “shoeboxes”. The walls of these boxes do not need to endure 14.51 lbs/inch², but only the pressure difference (or gradient) between 10⁻³ torr and 10⁻⁹ torr. The boxes are kept e.g. at 500-700° C. so that the sample can readily be maintained at a uniform temperature, the same as the box wall. Outside the shoeboxes the outer chamber pressure is very low. At low pressure, gases would not conduct much heat, so that the outer housing can be kept at room temperature without much need for cooling or insulation.

More particularly, the first, second and transport chambers may be constructed of thin steel having a thickness sufficient to withstand a pressure difference between a pressure inside each said chamber of between about 10⁻³ torr to about 10⁻⁶ torr and a pressure outside each chamber of between about 10⁻⁸ torr and about 10⁻⁹ torr.

Temperatures maintained in the first, second and transport boxes will vary depending on the gases and substrates being processed. Typically:
the first and second chambers are at different temperatures between about 200° C. and about 1000° C., and usually the first and second chambers are at different temperatures between about 500° C. and about 700° C.;
the first chamber may be at a temperature between about 200° C. and about 500° C. and the second chamber at a temperature in the range from above 500° C. to about 1000° C., and usually the second chamber is at a temperature in the range from above 500° C. to about 700° C.

In accordance with the invention, the epitaxial substrate may be epitaxial silicon, typically a silicon wafer.

The gas supplied to the first chamber may comprise an element selected from the group consisting of oxygen, carbon, nitrogen, phosphorus, sulfur, hydrogen, antimony, arsenic, aluminum, erbium, germanium, hafnium, rubidium and zirconium, and combinations thereof. Usually, the gas is oxygen or comprises carbon. A silicon-comprising compound may be supplied in gaseous form to said second chamber.

In the apparatus, the gas inlet to the second chamber to supply a gaseous silicon-comprising compound may also comprise means for delivering the gaseous silicon compound through said nozzle in a series of pulses of said compound in selected amounts. The means may be a programmed electrical switch. ALD is really a HV-CVD where the silane gas pressure is reduced to 10⁻³ torr or so. In fact, the silane gas such as SiH₄ can be delivered to the heated wafer surface by a gaseous pulse from a nozzle so that the wafer surface will receive uniformly one or two atomic layers for each pulse. The wafer surface preferably is kept at a very uniform temperature in order to achieve a uniform thermal cracking of the silane. The chamber walls are also at the wafer temperature, therefore the chamber walls will also be exposed and coated with silicon. The walls can be scrubbed periodically if necessary.

After adsorption of a first and second layer on the substrate, formation of layers in the first and second chamber may be repeated to form a plurality of periods each comprising alternating first and second layers. In such repeated alternating layers, the gas adsorbed in the first layer forming part of the first period, may form layers in succeeding periods, or a different gas may be used in the first chamber. For example, in production of a superlattice a phosphorous layer may be formed e.g. to stop oxygen atoms in Si/O layers from diffusing out.

By formation of a plurality of periods a superlattice can be formed on the substrate. The superlattice may comprise a plurality of epitaxially grown silicon layers sandwiched between adsorbed monolayers of oxygen. The superlattice may comprise between about 9 periods and about 100 periods. Instead of a Si/O superlattice, a Si/C superlattice may be formed, wherein the superlattice comprises a plurality of epitaxially grown silicon layers sandwiched between adsorbed monolayers of carbon. The Si/C superlattice may comprise between about 9 periods and about 100 periods.

The Si/O superlattice can be fabricated with a few Si layers per each atomic oxygen layer as an insulator or a few tens of silicon layers per atomic oxygen layer as a high-resistive silicon material.

The apparatus as shown in FIGS. 1 and 3 includes transporting means e.g. comprising a turntable, tracks on the turntable respectively extending from the turntable to the first, second and loading chambers, a holder for holding a substrate on the turntable, and means connectable to the holder for positioning the holder and moving it on the tracks. The holder may comprise a heating element.

Substrates such as silicon wafers can be held by thin metal plates made of stainless steel or molybdenum, with the back of the plate having a handle that can be reached by mechanical arms to position the plate in the chambers and to pass it through the gate-lock between the chambers. Heating of the wafer can be resistive of the plate via RF induced eddy currents in the metal. Gaseous silane may be delivered through a thermally insulated nozzle with electrical switch so that the gas source will be delivered in the form of a precise pulse with minimal residual gas flow.

The chambers as well as the outer housing are kept at UHV under turbo molecular pumps.

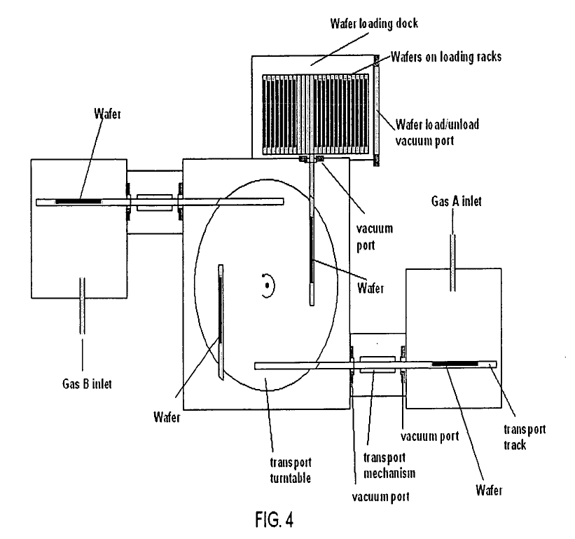

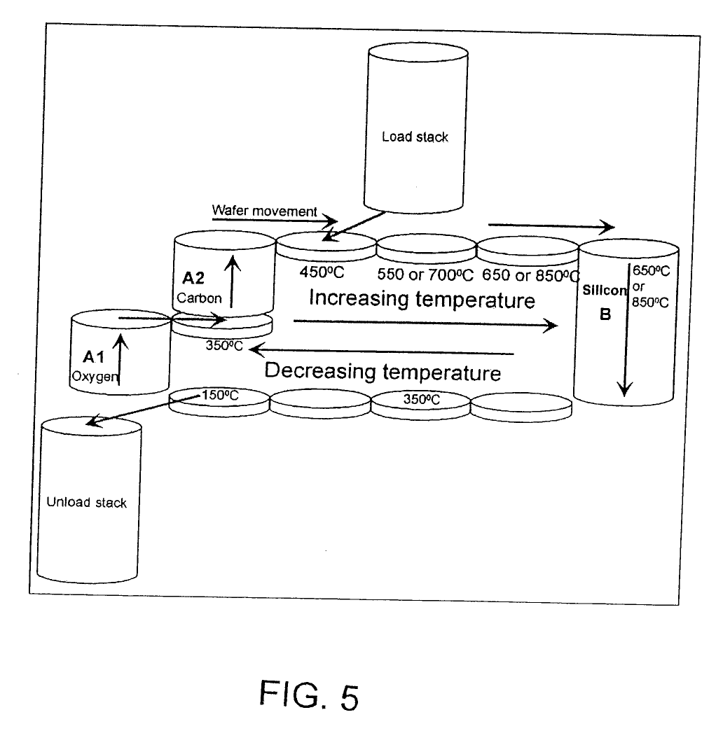

Reference is next made to FIGS. 4 and 5 for the fabrication of Si/O and/or Si/C Superlattice wafers.

FIG. 4 is a schematic diagram of a dual-chamber ALD system. Chambers A, B and T are maintained at pressure ˜10⁻⁶ Torr with Turbo pumps. Gasses A and B are injected into their respective chambers with insulated nozzles. The ALD system is kept at 500-700° C., and enclosed by a large UHV housing to enhance the ALD functions and to isolate the system from the ambient atmosphere.

FIG. 5 shows a multi-stage system to construct Si/O and/or Si/C superlattice. The system includes treatment stacks and temperature controlled plates with their spatial relationship shown. The Fig. shows also the location of the load and unload stacks.

With a much larger bandgap than silicon, Si/O and SiC can be used to construct devices serving high power and high temperature operations that silicon devices cannot. Conventional silicon oxide on silicon is amorphous and the SiC material is a very difficult crystal to construct. SiC does not have a liquid phase except at 2,800° C. and under 38 atmospheres of pressure so that it cannot form a single crystal ingot like silicon and be sliced into wafers. SiC powder is a low-cost grinding material, and its sublimation vapor at 1,800° C. can be used to grow SiC wafer from a template. Such SiC wafers, however, suffer from defects such as micropipes, high dislocation density, polytype, etc., caused mainly by the high temperature growth environment. More recent CVD using binary gas source(s) can reduce the thermal budget to 1,500° C. and below and thereby greatly reducing the SiC defect densities.

Using the silicon-based superlattice, the Si/O and Si/C superlattices make use of the silicon processing environment. They will grow from a silicon substrate to form the Si/O superlattice or will use the Si/O superlattice surface as an intermediate link to attach carbon-containing molecules such as CH₄ or C₂H₄. Note that, as oxygen absorbed on a silicon surface will be self-limiting at low temperature, the carbon-containing molecules attaching only to the oxygen treated surface will also be self-limiting. To incorporate molecules with a self-limiting process is an important aspect of this ALD disclosure, as it makes the controls of incorporating the gas source(s) to the crystal growth relatively simple.

Si/C Deposition Using Intermediate Si/O Superlattice

The Si/C superlattice is constructed on a silicon epi-wafer surface with monolayer of carbon coated on the lattice sites of oxygen in the Si/O structure, which in turn was constructed on the epi-silicon surface using its dimer formation as a catalyst. All molecular binding energies considered here are taken at the room temperature, but can be scaled to review the binding energies at slightly elevated temperatures in order to indicate various reaction possibilities. A bond with one eV is approximately 100 kJ/mole (96.375 kJ/m see for example, Handbook of Physics and Chemistry, CRC Press).
The epi-surface of silicon wafer has a dimer structure with the Si:Si bond at 225 kJ/m, less than Si:H bond of 300 kJ/m. Hydrogen atoms can boil away as H₂ gas, making use of the H:H bond at 436 kJ/m, and inducing the dimer formation. The dimers cannot revert back to the Si:H bonds without additional energy input.
Carbon source typically has its hydrogen binding energy at ˜400 kJ/m, or 100 kJ/m more than the silicon source. This difference is less than the difference between Si:C and Si:Si: bonds, which is 145 kJ/m. 400 kJ/m, however, is higher than the Si:C binding at 370 kJ/m, or 300 kJ/m is also higher than the Si:Si bond at 225 kJ/m, therefore CH₄ or SiH₄ would not attach to the silicon surface already sealed with a dimer structure at low temperatures where an additional 225 kJ/m will be needed to break the dimers. Multiple bonds could exchange energies only at higher temperatures; for example, empirically, silicon source with hydrogen can be deposited at 650° C., while carbon source with hydrogen can be deposited at 900° C. (J. H. Boo et. al. J Vac Sci Tech B21, 1071; 2003).
Upon exposing oxygen gas at 200° C. on silicon, O₂ would break (O:O has a binding energy of 500 kJ/m, the same as H2:O) and form Si:O double bonds at 800 kJ/m, but not SiO:O as the bond has only 110 kJ/m. The surface dimer pattern in RHEED (reflection high energy electron diffraction) image would disappear and be replaced by the 3-D pattern. Subsequent arrival of O₂ cannot be incorporated without the catalytic dimers, therefore the deposition of oxygen is self-limiting and would not alter the epi-structure. This is different from the conventional surface oxide with the SiO₂ formation.
The surface is now completely covered with a monolayer of Si/O, and the coverage of dangling atomic oxygen is self-limiting and uniform.
Raising temperature to 350° C. to loose up the hydrogen bonds of the carbon source, carbon can be added using CH₄ or C₂H₄, for example. The arrival of CH₄, with H:CH₃ bond at 439 kJ/m is not sufficient to resist the formation of C:O with its singe bond at 538 kJ/m plus possibly Si:C at 370 kJ/m, so that CH₃ would couple to the dangling oxygen, and form either Si:O:CH₃ or C:O:SiH₃ upon annealing. Some H₂ gas may form and leave, making use of the H:H bond at 436 kJ/m. Also there are no sufficient free carbon atoms around to form the tetrahedral Carbons with the Silicon.
The surface or subsurface is now covered with a complete monolayer of carbons on the oxygen sites without altering the epitaxy.
As both C and Si are isoelectronic, the RHEED pattern would not change due to any Si being replaced by C.
All lattice sites with oxygen are now covered with CH₃ (or C₂H₃) or SiH₃. Carbon atoms or CH₃ (or C₂H₃) cannot diffuse into silicon lattice much below the melting point of silicon at 1,428° C.
The surface is now heated from 350° C. to 650° C. to boil away the hydrogen atoms in the form of H₂ gas, making use of H:H binding at 436 kJ/m and the surface dimer formation.
At 650° C., the addition of three silicon to each carbon would compete against the C:O single bond at 538 kJ/m. The three Si:C bonds in the tetrahedral structure have an energy of 3×370=1,110 kJ/m, which is sufficient to detach many hydrogen bonds and allow them to form H₂ molecule and leave the surface.
Without H₂ and with Si binds directly with C, the O can be cleaved off from C and be ionized. Oxygen can either make use of O:O at 500 kJ/m to form O₂ at 850° C. and leave the surface, or remain in the lattice at 650° C.

At 650° C., surface silicon atoms would have sufficient mobility to move around and fall into the epitaxial state and location. The surface silicon would again form the dimer structure while cleaving off the H₂ gas, completing the superlattice formation for one period and be ready for the construction of the next period.
The C/Si ratio using CH₄ is under 20%; this ratio can be doubled by using C₂H₄ as the carbon source.
Without oxygen to establish the Si/O superlattice, the carbon source may deliver the carbon to either C or Si, and cannot be annealed due to the lack of carbon's atomic surface mobility. Also there is no easy way to meter the carbons for monolayer deposition with uniformity. Using the mobility of surface silicon alone for annealing may not be sufficient to achieve the desired epi-superlattice formation.

1. An atomic layer deposition apparatus for depositing a plurality of ultra-thin layers onto an epitaxial substrate, said apparatus comprising:
a first chamber having an inlet for a gas to be adsorbed on an epitaxial substrate;
a second chamber having an inlet for a gas to be adsorbed on said epitaxial substrate;
a transport chamber disposed between said first and second chambers for transporting and annealing said epitaxial substrate;
a loading chamber connected to the transport chamber for storing, loading and unloading epitaxial substrates, said loading chamber comprising a vacuum gate for isolating the loading chamber from the external atmosphere;
the transport chamber comprising transporting means for transferring epitaxial substrates to and from each of said first, second and loading chambers;
the first chamber being connected to the transport chamber by a first conduit and the second chamber being connected to the transport chamber by a second conduit, each conduit allowing passage of substrates and comprising a vacuum gate;
an outer chamber enclosing the first, second and transport chambers and at least partially enclosing said loading chamber;
means for heating the first, second and transport chambers to temperatures individually selected for each chamber;
means for evacuating the first, second, transport, loading and outer chambers to ultra high vacuum pressures individually selected for each chamber.

2. The apparatus according to claim 1, wherein the epitaxial substrate is epitaxial silicon.

3. The apparatus according to claim 2, wherein the epitaxial silicon substrate is a silicon wafer.

4. The apparatus according to claim 1, further comprising means for supplying a gas to the first chamber, said gas comprising an element selected from the group consisting of oxygen, carbon, nitrogen, phosphorus, sulfur, hydrogen, antimony, arsenic, aluminum, erbium, germanium, hafnium, rubidium and zirconium, and combinations thereof.

5. The apparatus according to claim 4, further comprising means for supplying a silicon-comprising compound in gaseous form to said second chamber.

6. The apparatus according to claim 5, wherein the means for supplying a gas to the first chamber comprises a supply of oxygen.

7. The apparatus according to claim 5, comprising an insulated nozzle and means for delivering the gaseous silicon compound through said nozzle in a series of pulses of said compound in selected amounts.

8. The apparatus according to claim 1, wherein the transporting means comprises a turntable, tracks on the turntable respectively extending from the turntable to the first, second and loading chambers, a holder for holding a substrate on the turntable, and means connectable to the holder for positioning the holder and moving it on the tracks.

9. The apparatus according to claim 8, wherein the holder comprises a heating element.

10. The apparatus according to claim 1, wherein the outer chamber comprises a wall constructed of steel sufficiently thick to withstand a pressure difference between a pressure inside said chamber of between about 10−8 torr and about 10−9 torr, and atmospheric pressure outside said chamber.

11. The apparatus according to claim 10, wherein the outer chamber is spheroidal.

12. The apparatus according to claim 1, wherein the outer chamber is insulated.

13. The apparatus according to claim 1, wherein the first, second and transport chambers are constructed of thin steel having a thickness sufficient to withstand a pressure difference between a pressure inside each said chamber of between about 10−3 torr to about 10−6 torr and a pressure outside each chamber of between about 10−8 torr and about 10−9 torr.

14. The apparatus according to claim 13, wherein the first, second and transport chambers are rectangular.

15. An atomic layer deposition process which comprises:
moving an epitaxial silicon substrate into a transport chamber located between a first chamber and a second chamber, said chambers being heated and evacuated to ultra high vacuum pressures;
transferring the substrate into the first chamber and introducing a gas for adsorption onto the substrate and formation of an adsorbed atomic first layer;
transferring the substrate having the first layer back into the transport chamber and then into the second chamber;
introducing a silicon-containing gas into the second chamber for adsorption onto the first layer and formation of an ultra-thin epitaxial silicon second layer;
maintaining different temperatures in the first and second chambers, said different temperatures being selected to form the first and second layers and maintain them without structural degradation.

16. The process according to claim 15, wherein the gas introduced into the first chamber forms an atomic layer comprising an element selected from the group consisting of oxygen, carbon, nitrogen, phosphorus, sulfur, hydrogen, antimony, arsenic, aluminum, erbium, germanium, hafnium, rubidium and zirconium, and combinations thereof.

17. The process according to claim 15, wherein the gas introduced into the first chamber forms an atomic layer of oxygen.

18. The process according to claim 15, which comprises introducing the silicon-containing gas as a series of pulses in exact selected amounts, thereby forming a plurality of ultra-thin epitaxial silicon layers.

19. The process according to claim 15, which comprises repeating the formation of layers in the first and second chambers to form a plurality of periods each comprising alternating first and second layers.

20. The process according to claim 19, wherein a superlattice is formed on the substrate.

21. The process according to claim 20, wherein the superlattice comprises a plurality of epitaxially grown silicon layers sandwiched between adsorbed monolayers of oxygen.

22. The process according to claim 21, wherein the superlattice comprises between about 9 periods and about 100 periods.

23. The process according to claim 20, wherein the superlattice comprises a plurality of epitaxially grown silicon layers sandwiched between adsorbed monolayers of carbon.

24. The process according to claim 23, wherein the superlattice comprises between about 9 periods and about 100 periods.

25. The process according to claim 15, wherein following adsorption of introduced gases, residual gases in the first and second chambers are removed by evacuation.

26. The process according to claim 15, which comprises maintaining the first and second chambers at a lower pressure than the pressure in the transport chamber such that residual gas in either of the first and second chambers does not enter the other of said chambers.

27. The process according to claim 15, which comprises enclosing the first, second and transport chambers in an outer chamber evacuated to an ultra high vacuum pressure, to maintain uniform, selected temperatures in the respective chambers.

28. The process according to claim 27, wherein the outer chamber is evacuated to a pressure of between about 10−8 torr and about 10−9 torr.

29. The process according to claim 15, wherein the first and second chambers are evacuated to a pressure of between about 10−3 torr to about 10−6 torr.

30. The process according to claim 15, wherein the first and second chambers are at different temperatures between about 200° C. and about 1000° C.

31. The process according to claim 15, wherein the first and second chambers are at different temperatures between about 500° C. and about 700° C.

32. The process according to claim 15, wherein the first chamber is at a temperature between about 200° C. and about 500° C. and the second chamber is at a temperature in the range from above 500° C. to about 1000° C.

33. The process according to claim 32, wherein the second chamber is at a temperature in the range from above 500° C. to about 700° C.

34. A process of applying a plurality of ultra-thin layers onto an epitaxial substrate, said process comprising the steps of:
(a) feeding an epitaxial substrate in the form of a wafer along a cyclical transport path,
(b) heating the wafer in stages from a temperature of 450° C. up to 850° C.,
(c) subjecting the heated wafer to silicon ions or silane vapor
(d) cooling the wafer to 150° C.,
(e) reheating the wafer to 350°,
(f) subjecting the reheated wafer to a successive deposition of at least one of oxygen and carbon, and
(g) repeating steps (a), (b), (c) and (d) to obtain the wafer with atomic layers of silicon with oxygen or carbon, thereon.

35. The process according to claim 34, wherein the silicon coated wafer is first coated with oxygen to form a superlattice thereof and thereafter the superlattice is subjected to a carbon-containing gas which coats lattice sites of the oxygen in the superlattice.

36. The process according to claim 35, wherein the carbon-containing gas is methane or ethane.

37. Apparatus for applying a plurality of ultra-thin layers onto an epitaxial substrate, said apparatus comprising:
means for feeding an epitaxial substrate, in the form of a wafer, along a cyclical transport path,
means for heating the wafer, in stages, from a temperature of 450° C. up to 850° C.,
a chamber connected to receive the heated wafer,
means for supplying silicon ions or silane vapor into said chamber to coat the substrate,
means for cooling the wafer to 150° C.,
means for reheating the wafer to 350°,
a second chamber for receiving the reheated wafer
means for introducing at least one of oxygen and carbon gas into said second chamber to form an atomic deposition on the silicon deposited wafer,
means to return the wafer to the cyclical transport path from which it is then separated, and
unloading station from which wafers are obtained with an atomic layer of silicon on which is formed a layer of oxygen or carbon.

38. The apparatus according to claim 37, wherein the silicon-coated wafer is subjected to oxygen in the second chamber to form a superlattice of silicon and oxygen, whereafter the wafer is subjected to a carbon-containing gas so that carbon attaches to lattice sites of the oxygen in the superlattice.
